(19) United States
(12) Patent Application Publication
(10) Pub. No.: US 2026/0058608 A1
(43) Pub. Date: Feb. 26, 2026

(54) CLASS C AMPLIFIER BIAS CIRCUIT

(71) Applicant: QUALCOMM Incorporated, San Diego, CA (US)

(72) Inventors: Muslum Emir AVCI, Marlborough, MA (US); Jing-Hwa CHEN, Sudbury, MA (US); Manoj Kumar ARIPIRALA, Maynard, MA (US); Xinwei WANG, Dunstable, MA (US); Xiangdong ZHANG, Westford, MA (US); Paul Brian SHEEHY, San Diego, CA (US)

(21) Appl. No.: 18/814,364

(22) Filed: Aug. 23, 2024

(51) Int. Cl. H03F 1/02; G05F 3/26; H03F 3/45

(52) U.S. Cl. CPC H03F 1/0288; G05F 3/267; H03F 3/45273; H03F 2200/451

(57) ABSTRACT

Bias circuits are provided for biasing an amplifier transistor for class C amplifier operation. In a first bias circuit, a pair of diode-connected transistors are arranged in series between ground and a current source. An upper transistor in the series has a resistor coupled between its base and collector. The collector of the upper transistor couples to a base of another transistor having an emitter coupled to a base of the amplifier transistor. In a second bias circuit, a current source drives a first transistor having a first resistor coupled between its emitter and base and a second resistor coupled between its base and collector. The collector of the first transistor couples to a base of a second transistor having an emitter coupled to a base of the amplifier transistor.

### TECHNICAL FIELD

The present application relates generally to amplifiers and more specifically, to a class C amplifier bias circuit.

### BACKGROUND

Amplifiers are classified depending upon their biasing. In a class C amplifier, an amplifier transistor is biased so that its output current is zero over more than one half of an input signal's sinusoidal cycle (the conduction angle being less than 180 degrees). Due to their high efficiency, class C amplifiers have numerous applications. For example, the peaking or auxiliary amplifier in a Doherty amplifier is typically biased to form a class C amplifier.

The peaking amplifier in a Doherty amplifier is often made using a hetero bipolar junction transistor (HBT) due to its advantageous high-frequency properties. A bias circuit biases the base of the HBT with a bias voltage that is less than the base-to-emitter voltage (VBE) voltage so that the desired limited conduction angle is achieved. The bias circuit should also be relatively low power, compact, and robust to process, voltage, and temperature variations.

### SUMMARY

In accordance with an aspect of the disclosure, an apparatus is provided that includes: a bias circuit, the bias circuit including: a first bipolar junction transistor having an emitter coupled to ground; a second bipolar junction transistor having an emitter coupled to a base and a collector of the first bipolar junction transistor; a first resistor coupled between a base and a collector of the second bipolar junction transistor; and a third bipolar junction transistor having a base coupled to the collector of the second bipolar junction transistor; and a class C amplifier including a fourth bipolar junction transistor, wherein an emitter of the third bipolar junction transistor is coupled to a base of the fourth bipolar junction transistor to bias the fourth bipolar junction transistor.

In accordance with another aspect of the disclosure, an apparatus is provided that includes: a bias circuit, the bias circuit including: a first bipolar junction transistor having an emitter coupled to ground; a first resistor coupled between a base and the emitter of the first bipolar junction transistor; a second resistor coupled between the base and a collector of the first bipolar junction transistor; a current source coupled to the collector of the first bipolar junction transistor; and a second bipolar junction transistor having a base coupled to the collector of the first bipolar junction transistor; and a class C amplifier including a third bipolar junction transistor, wherein an emitter of the second bipolar junction transistor is coupled to a base of the third bipolar junction transistor to bias the third bipolar junction transistor.

Finally, in accordance with yet another aspect of the disclosure, a method of biasing is provided that includes: conducting a first current through a diode-connected first bipolar junction transistor to generate a base-to-emitter voltage at a base and a collector of the diode-connected first bipolar junction transistor; conducting the first current through a first resistor coupled between a base and collector of a second bipolar junction transistor having an emitter coupled to a collector of the diode-connected first bipolar junction transistor to develop a collector voltage at the collector of the second bipolar junction transistor; charging a base of a third bipolar junction transistor with the collector voltage to develop a bias voltage at an emitter of the third bipolar junction transistor; and biasing a base of a fourth bipolar junction transistor with the bias voltage.

These and other advantageous features may be better appreciated through the following detailed description.

### BRIEF DESCRIPTION OF THE DRAWINGS

FIG. 1 illustrates a first bias circuit for biasing a class C amplifier transistor in accordance with an aspect of the disclosure.

FIG. 2 illustrates a second bias circuit for biasing a class C amplifier transistor in accordance with an aspect of the disclosure.

FIG. 3 illustrates a third bias circuit for biasing a class C amplifier transistor in accordance with an aspect of the disclosure.

FIG. 4 illustrates a Doherty amplifier in which the auxiliary amplifier transistor is biased by a bias circuit in accordance with an aspect of the disclosure.

FIG. 5 illustrates a transceiver in which the power amplifier is a Doherty amplifier including an auxiliary amplifier biased by a bias circuit in accordance with an aspect of the disclosure.

FIG. 6 illustrates a fourth bias circuit for biasing a class C amplifier transistor in accordance with an aspect of the disclosure.

FIG. 7 is a flowchart for a method of biasing an amplifier transistor in accordance with an aspect of the disclosure.

Implementations of the present disclosure and their advantages are best understood by referring to the detailed description that follows. It should be appreciated that like reference numerals are used to identify like elements illustrated in one or more of the figures.

### DETAILED DESCRIPTION

Several bias circuit architectures are provided for a class C amplifier. The following discussion will first focus on a bias circuit for the biasing of a class C amplifier bipolar junction transistor due to their advantageous high frequency performance. However, bias circuits for the biasing of a class C amplifier metal-oxide semiconductor field-effect transistor will also be discussed. In bipolar junction transistor implementations, the disclosed bias circuits produce a bias voltage that is a fraction of the VBE for a class C amplifier bipolar junction transistor. The bias circuits are advantageously compact and also track the base-to-emitter voltage (VBE) temperature variation of the class C amplifier bipolar junction transistor (BJT). The resulting temperature tracking of the VBE variation provides temperature compensation for the amplifier biasing.

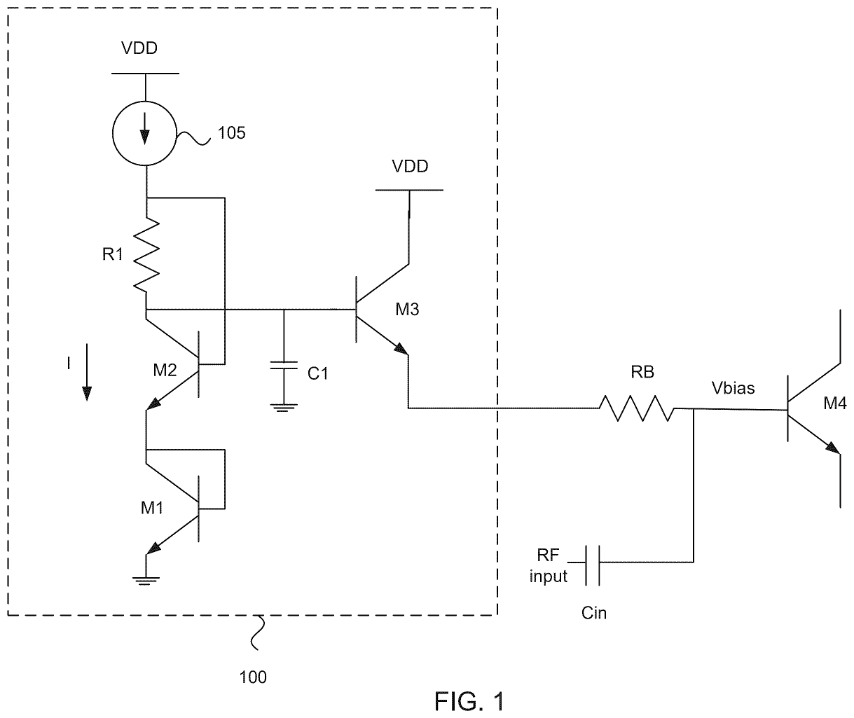

A first bipolar junction transistor implementation of a class C bias circuit 100 is shown in FIG. 1 for producing a bias voltage (Vbias) that is a fraction of the VBE for a class C amplifier bipolar junction transistor M4 (e.g., a hetero bipolar junction transistor). The amplifier transistor M4 is doped to be an NPN transistor but it will be appreciated that the amplifier transistor M4 may instead be doped to be a PNP transistor in alternative implementations. To produce the advantageous bias voltage that is a fraction of VBE, a pair of bipolar junction transistors such as hetero bipolar junction transistors (HBTs) M1 and M2 are stacked in series between ground and a resistor R1. The transistor M1 is diode connected and has its emitter coupled to ground. The transistor M2 is effectively diode connected such that the resistor R1 couples between the base and collector of the transistor M2. A first terminal of the resistor R1 couples to the collector of the transistor M2 whereas a second terminal of the resistor R1 couples to the base of the transistor M2. The emitter of the transistor M2 couples to the collector and base of the transistor M1. A current source 105 that couples between a node for a power supply voltage VDD and the second terminal of the resistor R1 drives a current I into the transistors M1 and M2.

Transistors M1 and M2 operate in the active region due to their conduction of the current I. The collector voltage of the transistor M1 is charged to VBE. Thus, the base voltage of the transistor M2 is 2VBE. Through Ohm's law, the collector voltage of the transistor M2 equals 2VBE-IR, where R is the resistance of the resistor R1. The collector of the transistor M2 couples to a base of a bipolar junction transistor M3 (e.g., another HBT). The collector of the transistor M3 couples to the node for the power supply voltage VDD. Transistor M3 is thus also biased into the active region with its emitter voltage equaling its base voltage (2VBE-IR) minus VBE, which equals VBE-IR. The resistor R1 is also referred to herein as a first resistor. Similarly, the transistor M1 is also denoted herein as a first transistor, the transistor M2 is also denoted herein as a second transistor, and the transistor M3 is also denoted herein as a third transistor. In addition, the class C amplifier transistor M4 is also denoted herein as a fourth transistor.

The doping of the transistors M1, M2, and M3 match the doping (NPN or PNP) of class C amplifier transistor M4. The following discussion will assume that transistors M1, M2, and M3 are NPN transistors but it will be appreciated that these transistors may be doped to be PNP transistors in an alternative implementation. The emitter of the transistor M3 couples through a base resistor RB to a base of the class C amplifier transistor M4. The base of the class C amplifier transistor M4 is thus biased to VBE-IR (disregarding the minor effect of the base current for the class C amplifier transistor M4 and the resulting Ohmic voltage across the base resistor). The class C amplifier transistor M4 is thus biased with a bias voltage that advantageously tracks the temperature variations of the base-to-emitter voltage for the class C amplifier transistor M4. In addition, since the bias voltage is a fraction of VBE, a class C biasing is achieved as desired.

The class C amplifier transistor M4 functions to amplify an RF input signal that couples to the base of the class C amplifier transistor M4 through a DC blocking capacitor Cin. To prevent this RF input signal from affecting the bias voltage, the base of the transistor M3 couples to ground through a capacitor C1. In this fashion, any RF noise from the RF input signal at the base of the transistor M3 is discharged to ground through the capacitor C1.

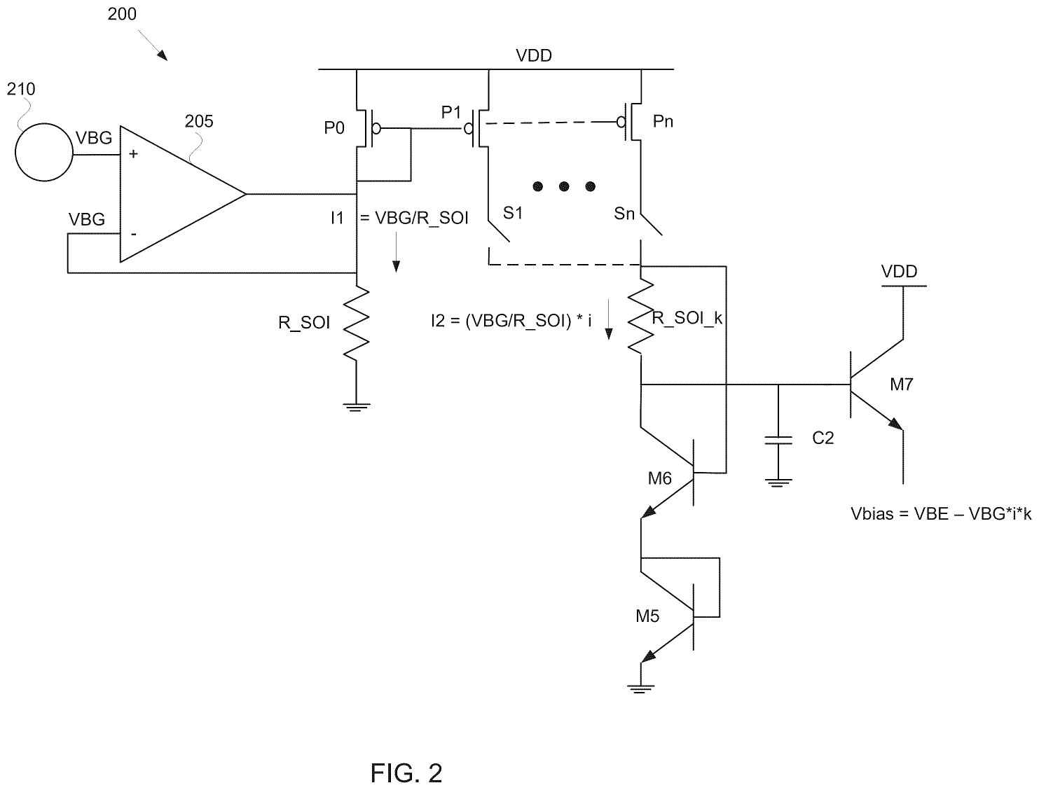

Although the bias voltage from the bias circuit 100 advantageously tracks the temperature variation of the base-to-emitter voltage of the class C amplifier transistor M4, the resistance R of the resistor R1 is subject to temperature, power supply voltage, and semiconductor manufacturing process variations. Bias circuit 100 may thus be modified as shown for a bias circuit 200 of FIG. 2 to substantially eliminate these temperature, voltage, and process effects on the bias voltage. In the bias circuit 200, a differential amplifier 205 receives a bandgap reference voltage VBG from a bandgap reference voltage source 210 at a first input terminal (e.g., a non-inverting input terminal). A second input terminal (e.g., an inverting input terminal) of the differential amplifier 205 couples to a first terminal of a second resistor such as a silicon-on-insulator resistor R_SOI that has a second terminal coupled to ground. In alternative implementations, the resistor R_SOI may instead be constructed using other suitable manufacturing technologies.

An output terminal of the differential amplifier 205 also couples to the first terminal of the resistor R_SOI. Feedback through the differential amplifier 205 charges its non-inverting input terminal (and thus the first terminal of the resistor R_SOI) to the bandgap reference voltage VBG. With the first terminal of the resistor R_SOI charged to the bandgap reference voltage VBG and its second terminal grounded, the resistor R_SOI conducts a reference current VBG/R_SOI to ground. This current is then mirrored through a current mirror such as formed by a diode-connected p-type metal-oxide semiconductor (PMOS) transistor P0 and a plurality of n PMOS current-mirror transistors ranging from a first current-mirror transistor P1 to an nth current-mirror transistor Pn, where n is positive integer. The diode-connected transistor P0 has a source coupled to a node for the power supply voltage VDD and a drain and gate coupled to the output terminal of the differential amplifier 205 (and also to the first terminal of the resistor R_SOI). Each current-mirror transistor has a source coupled to the power supply node and a gate coupled to the gate and drain of the diode-connected transistor P0. In addition, the drain of each current-mirror transistor couples through a corresponding switch (e.g., a transistor switch) to a first terminal of a resistor such as a variable silicon-on-insulator resistor R_SOI_k. There are thus n switches corresponding to the n current-mirror transistors ranging from a first switch S1 to an nth switch Sn. For illustration clarity, only the first current-mirror transistor P1, the nth current-mirror transistor Pn and their corresponding first switch S1 and nth switch Sn are shown in FIG. 2.

In an alternative implementation, just a single current-mirror transistor may be used. In that case, there would be no need for a corresponding switch. In yet another alternative implementation, the variable current mirror may be formed using n-type metal-oxide semiconductor (NMOS) transistors. Referring again to FIG. 2, if a given one of the switches is closed, the corresponding current-mirror transistor will conduct a mirrored current into the variable resistor R_SOI_k. If i of the switches are closed (where i is a positive integer less than or equal to n), then a total current I2 mirrored into the variable resistor R_SOI_k is (VBG/R_SOI)*i. This expression for the total current I2 assumes that each current-mirror transistor is matched (has the same size) as the diode-connected transistor. More generally, the magnitude of the current I2 also depends upon the relative size of each current-mirror transistor as compared to the size of the diode connected transistor P0. The combination of a current-mirror transistor and its corresponding switch is also denoted herein as a current-mirror branch.

The current I2 conducts through a serially connected pair of bipolar junction transistors M5 and M6 that are arranged analogously as discussed for transistors M1 and M2. Transistor M5 is diode connected and has its emitter coupled to ground. Transistor M6 is effectively diode connected such that the resistor R_SOI_k couples between the base and collector of the transistor M6. A first terminal of the resistor R_SOI_k couples to the collector of the transistor M6 whereas a second terminal of the resistor R_SOI_k couples to the base of the transistor M6. The emitter of transistor M6 couples to the collector and base of the transistor M5.

Transistors M5 and M6 operate in the active region as they both conduct an emitter current of I2. The collector voltage of the transistor M5 equals VBE. Thus, the base voltage of transistor M6 is 2VBE. Through Ohm's law, the collector voltage of the transistor M6 equals 2VBE-I2*R_SOI*k, where R_SOI*k is the resistance of the variable resistor R_SOI_k. The collector voltage of transistor M6 thus equals 2VBE−(VBG/R_SOI)*I*R_SOI*k=2VBE-VBG*i*k.

The collector of transistor M6 couples to a base of a bipolar junction transistor M7 having a collector coupled to the node for the power supply voltage VDD. An emitter voltage of the transistor M7 thus functions as a bias voltage Vbias equaling VBE-VBG*i*k. This bias voltage may then couple to the base of a class C amplifier transistor such as transistor M4 (not illustrated in FIG. 2) analogously as discussed for bias circuit 100. The bandgap reference voltage source 210 may be temperature compensated so that the temperature dependence of the bandgap reference voltage VBG is substantially eliminated. In this fashion, the dependence of the bias voltage on any temperature, volage, or process variations in the resistance of the variable resistor R_SOI_k is also substantially eliminated since the bias voltage equals VBE minus a multiple of the bandgap reference voltage VBG. The bandgap reference voltage VBG may be a divided version of the semiconductor bandgap voltage within the bandgap reference voltage source 210. By an appropriate setting of the variables i and k, the desired fraction of VBE is thus achieved for the bias voltage. A capacitor C2 couples between the base of the transistor M7 and ground to conduct any RF noise to ground analogously as discussed for the capacitor C1 of bias circuit 100. In one implementation, transistors M5, M6, and M7 may all comprise hetero bipolar junction transistors. In bias circuit 200, transistors M5, M6, and M7 are all doped to be NPN transistors but instead may be doped PNP in alternative implementations.

The resistor R_SOI_k is also referred to herein as a first resistor. Similarly, the transistor M5 is also denoted herein as a first transistor, the transistor M6 is also denoted herein as a second transistor, and the transistor M7 is also denoted herein as a third transistor. In addition, the resistor R_SOI is also denoted herein as a second resistor.

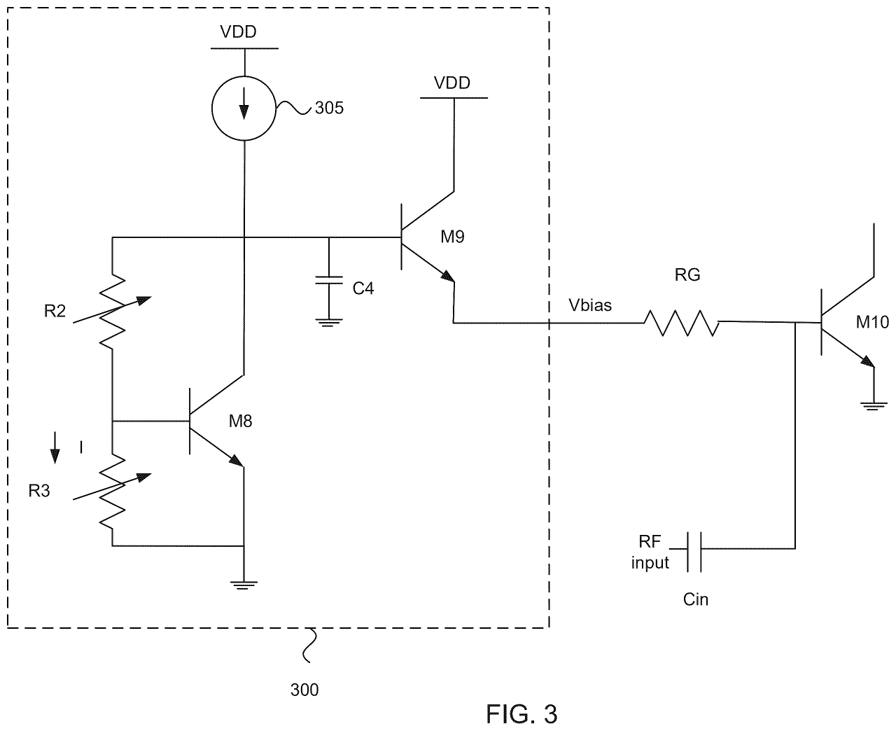

An alternative bias circuit 300 is shown in FIG. 3. A current source 305 couples between a collector of a bipolar junction transistor M8 and a node for the power supply voltage VDD. An emitter of the transistor M8 couples to ground whereas a variable resistor R3 couples between the emitter and the base of transistor M8. The transistor M8 is biased by the current from the current source 305 to function in the active region. The base voltage of the transistor M8 thus equals VBE, which forces the variable resistor R3 to conduct a current I equaling VBE/R3, where R3 is also the resistance of the variable resistor R3. Another variable resistor R2 couples between the base and collector of the transistor M8. Variable resistors R2 and R3 may instead each comprise a fixed resistor in alternative implementations. Since the base current for the transistor M8 is relatively small, the variable resistor R2 will also substantially conduct the current I equaling VBE/R3 conducted by the variable resistor R3.

Through Ohm's law, the collector voltage of the transistor M8 thus substantially equals VBE+I*R2, where R2 is also the resistance of the variable resistor R2. The collector voltage of transistor M8 may therefore be restated as equaling VBE+(VBE/R3)*R2. The collector of the transistor M8 couples to a base of a bipolar junction transistor M9 having a collector coupled to the node for the power supply voltage VDD. Transistor M9 is also biased to function in the active region so that its emitter voltage equals (VBE/R3)*R2. The emitter of the transistor M9 couples through a base resistor RB to a base of a class C amplifier bipolar junction transistor M10. The emitter voltage of the transistor M9 thus functions as a bias voltage Vbias that equals a fraction of VBE. In this fashion, the bias circuit 300 biases the amplifier transistor M10 for class C operation with a bias voltage that advantageously tracks the VBE temperature variation for the amplifier transistor M10. An RF input signal couples to the base of the amplifier transistor M10 through a DC blocking input capacitor Cin. To prevent any RF noise from the RF input signal from affecting the bias voltage Vbias, the base of the transistor M9 couples to ground through a capacitor C3 that functions analogously as discussed for the capacitor C1. The transistors M8, M9, and M10 are all doped NPN but instead may be doped PNP in alternative implementations. The variable resistor R3 is also referred to herein as a first resistor. Similarly, the variable resistor R2 is also denoted herein as a second resistor. The transistor M8 is also denoted herein as a first transistor, the transistor M7 is also denoted herein as a second transistor, and the transistor M10 is also denoted herein as a third transistor.

An example class C amplifier application that is advantageously biased by a bias circuit as disclosed herein will now be discussed. For example, the high peak-to-average-power-ratio (PAPR) of orthogonal frequency division multiplexing (OFDM) such as used in fifth generation (5G) telecommunication systems poses a dilemma for amplifiers. Should an amplifier be biased for efficient operation at the peak power of an OFDM signal, the amplifier will then operate with poor efficiency while the OFDM signal power is below this peak power. This lower efficiency would then be particularly problematic since the majority of the signal transmission occurs with the OFDM signal power below the peak power. Should the amplifier instead be biased for efficient operation at the average power of the OFDM signal, clipping or saturation then occurs when the OFDM signal transitions to its peak power.

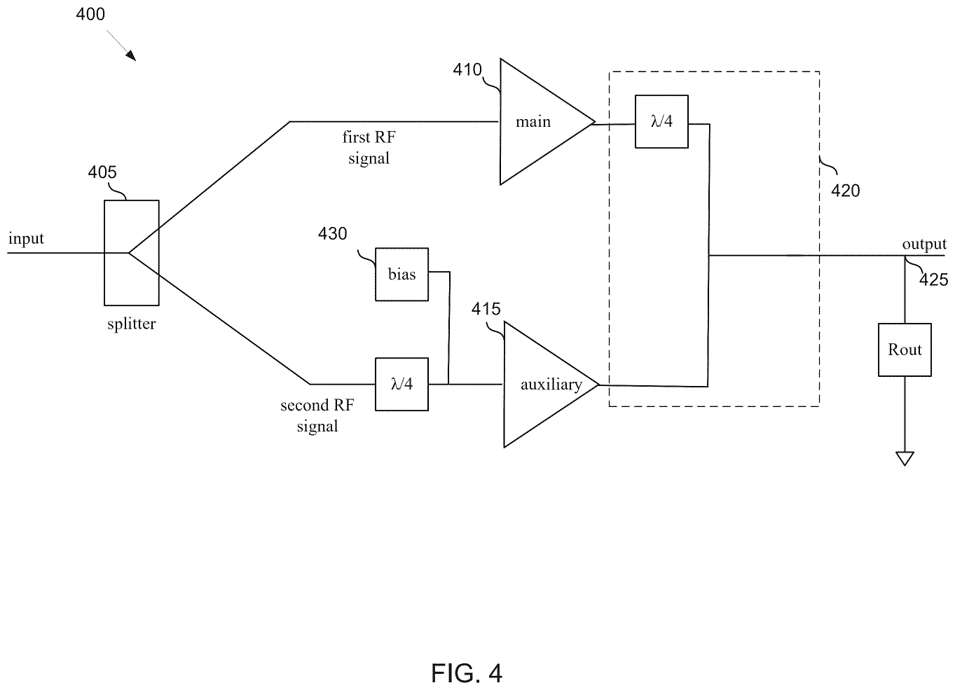

A Doherty amplifier solves this dilemma because a Doherty amplifier includes a main amplifier and an auxiliary amplifier that combine for peak efficiency not only at the average power of the radio frequency (RF) input signal but also at peak power of the RF input signal. A Doherty amplifier 400 is illustrated in FIG. 4. An RF input signal (input) is split equally in a splitter 405 into a first RF signal and a second RF signal. The first RF signal propagates over a first transmission line having a first electrical length to form a first input signal to a main amplifier 410. The second RF signal propagates over a second transmission line to form a second input signal to an auxiliary amplifier 415. The second transmission line has a second electrical length (e.g., potentially implemented by a phase shifter or other technique) that is greater than the first electrical length by M4, where λ is the carrier wavelength of the RF input signal. Given this electrical length difference for the propagation of the first and second split signals, a current conducted by the main amplifier 410 at peak power is delayed in phase by 90° (a quadrature phase relationship) with respect to a current conducted by the auxiliary amplifier 415 at peak power.

A bias circuit (not illustrated) biases the main amplifier 410 to be efficient for the average power of the RF input signal. For example, the main amplifier 410 may be biased to function as a class B (or a class AB) amplifier. In contrast, a bias circuit 430 as disclosed herein biases an amplifier transistor (not illustrated) in the auxiliary amplifier 415 for class C operation. Transistors M4 and M10 discussed earlier are examples of such an amplifier transistor. Bias circuit 430 may be implemented as discussed for any of the bias circuits 100, 200, and 300.

A combining network 420 combines the output signals from each of the main amplifier 410 and the auxiliary amplifier 415 to produce a combined RF output signal (output) at an output node 425. The combining network 420 includes an output transmission line extending from an output terminal of the main amplifier 410 to a combining node 425. This output transmission line has an electrical length that is longer by λ/4 than an output transmission line from an output terminal of the auxiliary amplifier 415 to the node 425. Node 425 is loaded by an output load Rout. The bias circuit 430 biases the auxiliary amplifier 415 so that the auxiliary amplifier 415 cuts off, for example, at 6 dB from the peak power of the RF output signal.

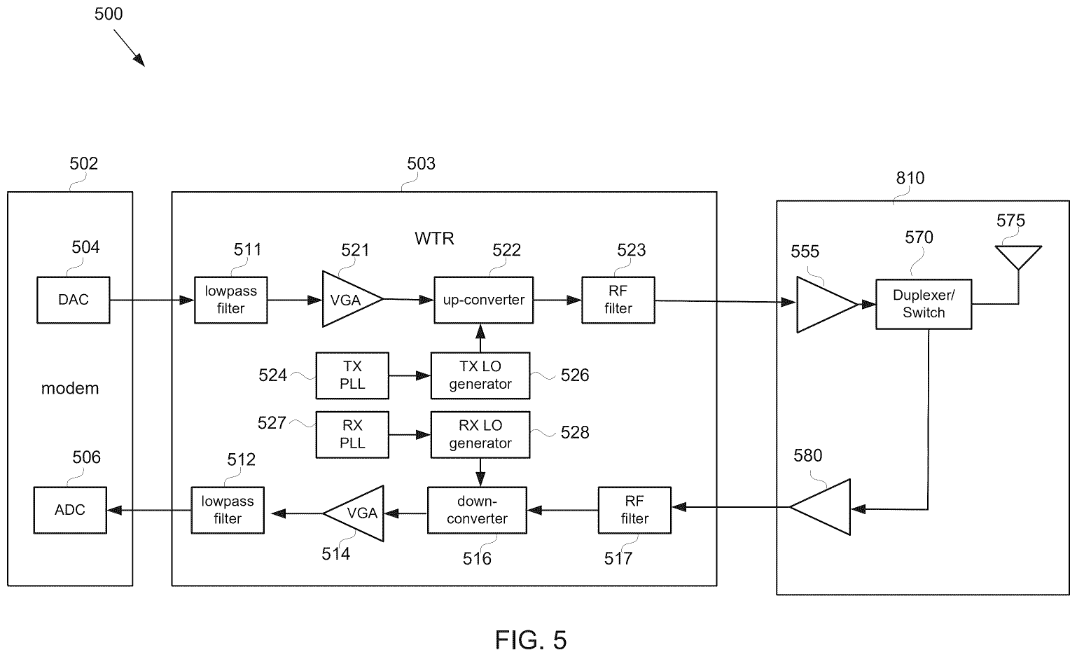

A class C amplifier including a bias circuit as disclosed herein may be advantageously incorporated into any suitable transceiver within a wireless communication device. An example wireless communication device 500 is shown in FIG. 5. A modem 502 (which may also be denoted as a baseband processor) includes at least one digital-to-analog converter (DAC) 504 for generating an analog transmit signal. A wireless transceiver integrated circuit (WTR) 503 includes a lowpass filter 511 for filtering the analog transmit signal to provide a filtered analog signal to a variable gain amplifier (VGA) 521. An up-converter 522 (such as one or more mixers) up converts an amplified analog signal from the VGA 521 in frequency to produce an RF signal. For example, the up-converter 522 may mix the amplified analog signal with a local oscillator (LO) signal from a transmit (TX) LO generator 526. An oscillator such as a TX phase-locked loop (PLL) 524 clocks the TX LO generator 526 for the generation of the TX LO signal. An RF filter 523 filters the RF signal from the up-converter to produce an RF input signal.

A front-end module 510 includes a power amplifier 555 for amplifying the RF input signal. It will be appreciated that additional stages of amplification of the RF input signal prior to the power amplifier 555 such as a pre-driver amplifier (not illustrated) and a driver amplifier (not illustrated) may also be used in alternative implementations. The power amplifier 555 may be implemented as a Doherty amplifier that is biased as discussed with respect to FIG. 4. An amplified RF output signal from the power amplifier 555 passes through an antenna switch module (duplexer/switch) 570 to an antenna(s) 575 for wireless transmission.

During a receive mode, a received RF signal from the antenna(s) 575 passes through the antenna switch module 570 to a low-noise amplifier 580. The WTR 503 also includes an RF filter 517 for filtering an amplified RF received signal from the LNA 580. A down-converter 516 (such as one or more mixers) down converts the filtered RF signal from the RF filter 517 in frequency to produce a down-converted analog signal. For example, the down-converter 516 may mix the filtered RF signal with an LO signal from a receive (RX) LO generator 528. An oscillator such as an RX phase-locked loop (PLL) 527 clocks the RX LO generator 528 for the generation of the RX LO signal. Another VGA 514 amplifies the down-converted analog signal from the down-converter 516 to drive a lowpass filter 512 that provides a filtered analog signal to an analog-to-digital (ADC) 506 in modem 502. An analog-to-digital converter (ADC) 506 recovers the digital baseband signal for further processing by modem 502. It will be appreciated that WTR 503 is merely exemplary and that other transceiver architectures may be used in conjunction with the class C amplifier biasing disclosed herein.

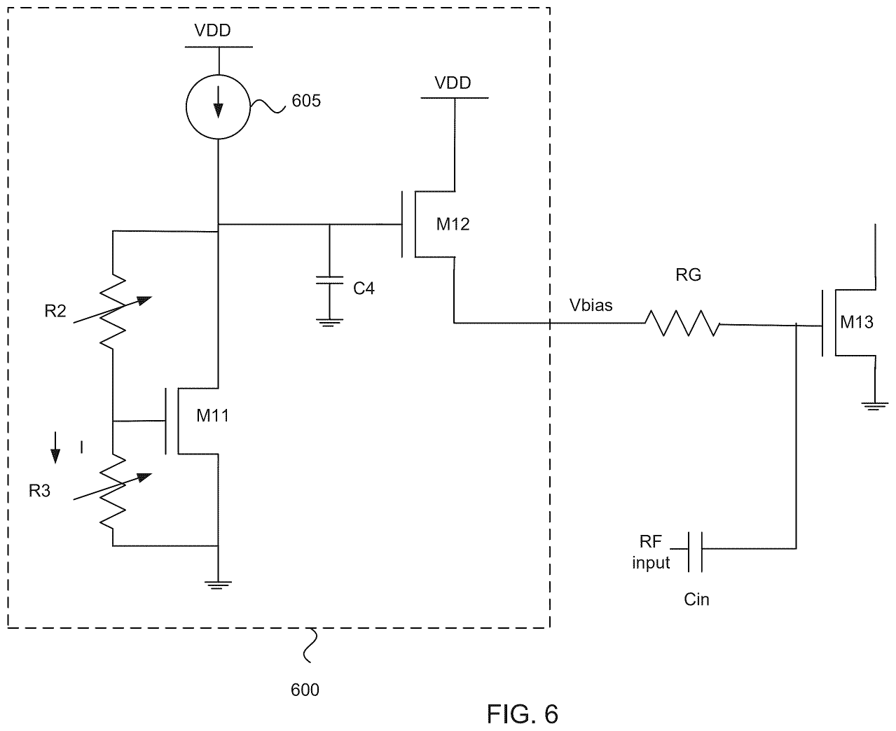

Although the use of a bipolar junction transistor such as a hetero bipolar junction transistor to implement the class C amplifier transistor provides advantageous higher frequency performance, a metal-oxide semiconductor field-effect transistor (MOSFET) may be used to form the class C amplifier transistor depending upon the application. The bias circuits disclosed herein are readily modified to bias a MOSFET. For example, the bias circuit 300 may be modified to form a MOSFET bias circuit 600 as shown in FIG. 6. A current source 605 couples between a drain of an NMOS transistor M11 and a node for the power supply voltage VDD. A source of the transistor M11 couples to ground whereas a variable resistor R3 couples between the source and the gate of transistor M11. The transistor M11 is biased by the current from the current source 605 to function in the saturation region. The gate voltage of the transistor M11 thus equals the threshold voltage Vt, which forces the variable resistor R3 to conduct a current I equaling Vt/R3, where R3 is also the resistance of the variable resistor R3. Another variable resistor R2 couples between the gate and drain of the transistor M11.

Through Ohm's law, the drain voltage of the transistor M11 thus substantially equals Vt+(I)*R2, where R2 is also the resistance of the variable resistor R2. The drain voltage may be restated as equaling Vt+ (Vt/R3)*R2. The drain of the transistor M11 couples to a gate of an NMOS transistor M12 having a drain coupled to the node for the power supply voltage VDD. Transistor M12 is also biased to function in the saturation region so that its source voltage equals (Vt/R3)*R2. The source of the transistor M12 couples through a gate resistor RG to a gate of a class C amplifier NMOS transistor M13. The source voltage of the transistor M12 thus functions as a bias voltage Vbias that equals a fraction of Vt. In this fashion, the bias circuit 600 biases the amplifier transistor M13 for class C operation with a bias voltage that advantageously tracks the Vt temperature variation for the amplifier transistor M13. An RF input signal couples to the base of the amplifier transistor M13 through a DC blocking input capacitor Cin. To prevent any RF noise from the RF input signal from affecting the bias voltage Vbias, the base of the transistor M12 couples to ground through a capacitor C4 that functions analogously as discussed for the capacitor C1. The transistors M11, M12, and M13 may all be PMOS transistors in alternative implementations.

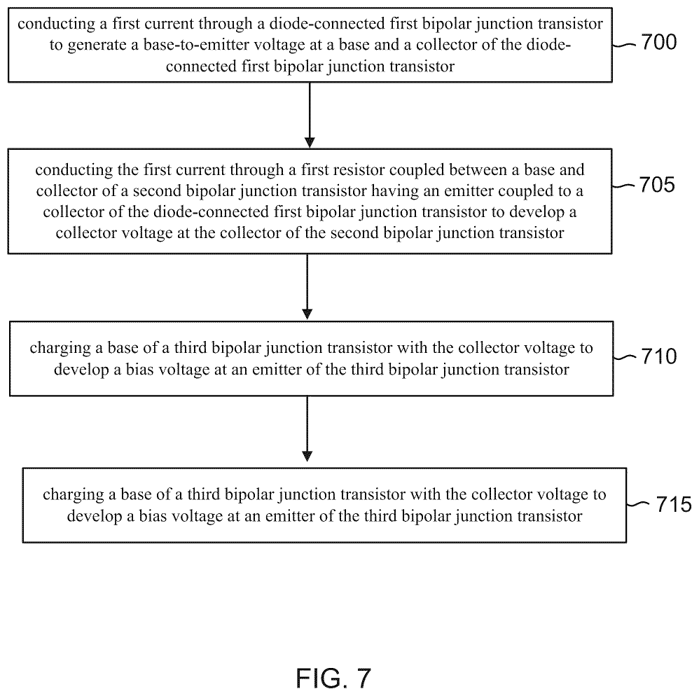

An example method of biasing will now be discussed with respect to the flowchart of FIG. 7. The method includes an act 700 of conducting a first current through a diode-connected first bipolar junction transistor to generate a base-to-emitter voltage at a base and a collector of the diode-connected first bipolar junction transistor. The generation of VBE at the base and collector of either transistor M1 in the bias circuit 100 or transistor M5 in the bias circuit 200 is an example of act 700. The method also includes an act 705 of conducting the first current through a first resistor coupled between a base and collector of a second bipolar junction transistor having an emitter coupled to a collector of the diode-connected first bipolar junction transistor to develop a collector voltage at the collector of the second bipolar junction transistor. The generation of the collector voltage for either transistor M2 in the bias circuit 100 or transistor M6 in the bias circuit 200 is an example of act 705. The method further includes an act 710 of charging a base of a third bipolar junction transistor with the collector voltage to develop a bias voltage at an emitter of the third bipolar junction transistor. The development of the bias voltage Vbias at the emitter of transistor M3 in the bias circuit 100 or at the emitter of transistor M7 is an example of act 710. Finally, the method includes an act 715 of biasing a base of a fourth bipolar junction transistor with the bias voltage. The biasing of the amplifier transistor M4 by either of the bias circuits 100 or 200 is an example of act 715.

Some example implementations will now be summarized through the following numbered clauses:

Clause 1. An apparatus, comprising:
a bias circuit, the bias circuit including:
a first bipolar junction transistor having an emitter coupled to ground;
a second bipolar junction transistor having an emitter coupled to a base and a collector of the first bipolar junction transistor;
a first resistor coupled between a base and a collector of the second bipolar junction transistor; and
a third bipolar junction transistor having a base coupled to the collector of the second bipolar junction transistor; and
a class C amplifier including a fourth bipolar junction transistor, wherein an emitter of the third bipolar junction transistor is coupled to a base of the fourth bipolar junction transistor to bias the fourth bipolar junction transistor.

Clause 2. The apparatus of clause 1, further comprising:
a capacitor coupled between the base of the third bipolar junction transistor and ground.

Clause 3. The apparatus of any of clauses 1-2, further comprising:
a voltage source;
a differential amplifier having a first input terminal coupled to the voltage source;
a second resistor having a first terminal coupled to a second input terminal of the differential amplifier and to an output terminal of the differential amplifier and having a second terminal coupled to ground; and
a current mirror configured to mirror a current conducted by the second resistor into the first resistor.

Clause 4. The apparatus of clause 3, wherein the current mirror comprises a diode-connected transistor and a plurality of current-mirror branches, each current-mirror branch comprising a current-mirror transistor having a gate coupled to a gate of the diode-connected transistor and a switch coupled between the current-mirror transistor and the first resistor.

Clause 5. The apparatus of clause 4, wherein the diode-connected transistor comprises a diode-connected PMOS transistor having a source coupled to a node for a power supply voltage and a drain coupled to the output terminal of the differential amplifier, and wherein each current-mirror transistor comprises a current-mirror PMOS transistor having a source coupled to the node for the power supply voltage.

Clause 6. The apparatus of any of clauses 3-5, wherein the first resistor is a variable resistor.

Clause 7. The apparatus of any of clauses 3-6, wherein the first resistor and the second resistor each comprises a silicon-on-insulator resistor.

Clause 8. The apparatus of any of clauses 3-7, wherein the voltage source comprises a bandgap reference voltage source.

Clause 9. The apparatus of any of clauses 1-8, wherein each of the first bipolar junction transistor, the second bipolar junction transistor, the third bipolar junction transistor, and the fourth bipolar junction transistor comprises a hetero bipolar junction transistor.

Clause 10. The apparatus of clause 9, wherein each hetero bipolar junction transistor comprises an NPN hetero bipolar junction transistor.

Clause 11. The apparatus of claim 1, wherein the class C amplifier is an auxiliary amplifier in a Doherty amplifier.

Clause 12. An apparatus, comprising:
a bias circuit, the bias circuit including:
a first bipolar junction transistor having an emitter coupled to ground;
a first resistor coupled between a base and the emitter of the first bipolar junction transistor;
a second resistor coupled between the base and a collector of the first bipolar junction transistor;
a current source coupled to the collector of the first bipolar junction transistor; and
a second bipolar junction transistor having a base coupled to the collector of the first bipolar junction transistor; and
a class C amplifier including a third bipolar junction transistor, wherein an emitter of the second bipolar junction transistor is coupled to a base of the third bipolar junction transistor to bias the third bipolar junction transistor.

Clause 13. The apparatus of clause 12, wherein the first resistor and the second resistor each comprises a variable resistor.

Clause 14. The apparatus of any of clauses 12-13, further comprising:
a capacitor coupled between the base of the second bipolar junction transistor and ground.

Clause 15. The apparatus of any of clauses 12-14, wherein the class C amplifier is an auxiliary amplifier in a Doherty amplifier.

Clause 16. The apparatus of any of clauses 12-15, wherein the first bipolar junction transistor, the second bipolar junction transistor, and the third bipolar junction transistor each comprises an NPN hetero bipolar junction transistor.

Clause 17. A method of biasing, comprising:
conducting a first current through a diode-connected first bipolar junction transistor to generate a base-to-emitter voltage at a base and a collector of the diode-connected first bipolar junction transistor;
conducting the first current through a first resistor coupled between a base and collector of a second bipolar junction transistor having an emitter coupled to a collector of the diode-connected first bipolar junction transistor to develop a collector voltage at the collector of the second bipolar junction transistor;
charging a base of a third bipolar junction transistor with the collector voltage to develop a bias voltage at an emitter of the third bipolar junction transistor; and
biasing a base of a fourth bipolar junction transistor with the bias voltage.

Clause 18. The method of clause 17, further comprising:
coupling a radio frequency input signal to the base of the fourth bipolar junction transistor to amplify the radio frequency input signal.

Clause 19. The method of any of clauses 17-18, further comprising:
charging an output terminal of a differential amplifier to a bandgap reference voltage to cause a second resistor to conduct a reference current; and
mirroring the reference current through a current mirror to form the first current conducted through the first resistor.

Clause 20. The method of clause 19, further comprising:
adjusting a magnitude of the first current and a resistance of the first resistor to tune the bias voltage.

As those of some skill in this art will by now appreciate and depending on the particular application at hand, many modifications, substitutions and variations can be made in and to the materials, apparatus, configurations and methods of use of the devices of the present disclosure without departing from the scope thereof as defined by the appended claims. In light of this, the scope of the present disclosure should not be limited to that of the particular implementations illustrated and described herein, as they are merely by way of some examples thereof, but rather, should be fully commensurate with that of the claims appended hereafter and their functional equivalents.

What is claimed is:

1. An apparatus, comprising:
a bias circuit, the bias circuit including:
a first bipolar junction transistor having an emitter coupled to ground;
a second bipolar junction transistor having an emitter coupled to a base and a collector of the first bipolar junction transistor;
a first resistor coupled between a base and a collector of the second bipolar junction transistor; and
a third bipolar junction transistor having a base coupled to the collector of the second bipolar junction transistor; and
a class C amplifier including a fourth bipolar junction transistor, wherein an emitter of the third bipolar junction transistor is coupled to a base of the fourth bipolar junction transistor to bias the fourth bipolar junction transistor.

2. The apparatus of claim 1, wherein the bias circuit further includes:
a capacitor coupled between the base of the third bipolar junction transistor and ground.

3. The apparatus of claim 1, wherein the bias circuit further includes:
a voltage source;
a differential amplifier having a first input terminal coupled to the voltage source;
a second resistor having a first terminal coupled to a second input terminal of the differential amplifier and to an output terminal of the differential amplifier and having a second terminal coupled to ground; and
a current mirror configured to mirror a current conducted by the second resistor into the first resistor.

4. The apparatus of claim 3, wherein the current mirror comprises a diode-connected transistor and a plurality of current-mirror branches, each current-mirror branch comprising a current-mirror transistor having a gate coupled to a gate of the diode-connected transistor and a switch coupled between the current-mirror transistor and the first resistor.

5. The apparatus of claim 4, wherein the diode-connected transistor comprises a diode-connected PMOS transistor having a source coupled to a node for a power supply voltage and a drain coupled to the output terminal of the differential amplifier, and wherein each current-mirror transistor comprises a current-mirror PMOS transistor having a source coupled to the node for the power supply voltage.

6. The apparatus of claim 3, wherein the first resistor is a variable resistor.

7. The apparatus of claim 3, wherein the first resistor and the second resistor each comprises a silicon-on-insulator resistor.

8. The apparatus of claim 3, wherein the voltage source comprises a bandgap reference voltage source.

9. The apparatus of claim 1, wherein each of the first bipolar junction transistor, the second bipolar junction transistor, the third bipolar junction transistor, and the fourth bipolar junction transistor comprises a hetero bipolar junction transistor.

10. The apparatus of claim 9, wherein each hetero bipolar junction transistor comprises an NPN hetero bipolar junction transistor.

11. The apparatus of claim 1, wherein the class C amplifier is an auxiliary amplifier in a Doherty amplifier.

12. An apparatus, comprising:
a bias circuit, the bias circuit including:
a first bipolar junction transistor having an emitter coupled to ground;
a first resistor coupled between a base and the emitter of the first bipolar junction transistor;
a second resistor coupled between the base and a collector of the first bipolar junction transistor;
a current source coupled to the collector of the first bipolar junction transistor; and
a second bipolar junction transistor having a base coupled to the collector of the first bipolar junction transistor; and
a class C amplifier including a third bipolar junction transistor, wherein an emitter of the second bipolar junction transistor is coupled to a base of the third bipolar junction transistor to bias the third bipolar junction transistor.

13. The apparatus of claim 12, wherein the first resistor and the second resistor each comprises a variable resistor.

14. The apparatus of claim 12, wherein the bias circuit further includes:
a capacitor coupled between the base of the second bipolar junction transistor and ground.

15. The apparatus of claim 12, wherein the class C amplifier is an auxiliary amplifier in a Doherty amplifier.

16. The apparatus of claim 12, wherein the first bipolar junction transistor, the second bipolar junction transistor, and the third bipolar junction transistor each comprises an NPN hetero bipolar junction transistor.

17. A method of biasing, comprising:
conducting a first current through a diode-connected first bipolar junction transistor to generate a base-to-emitter voltage at a base and a collector of the diode-connected first bipolar junction transistor;
conducting the first current through a first resistor coupled between a base and collector of a second bipolar junction transistor having an emitter coupled to a collector of the diode-connected first bipolar junction transistor to develop a collector voltage at the collector of the second bipolar junction transistor;
charging a base of a third bipolar junction transistor with the collector voltage to develop a bias voltage at an emitter of the third bipolar junction transistor; and
biasing a base of a fourth bipolar junction transistor with the bias voltage.

18. The method of claim 17, further comprising:
coupling a radio frequency input signal to the base of the fourth bipolar junction transistor to amplify the radio frequency input signal.

19. The method of claim 17, further comprising:
charging an output terminal of a differential amplifier to a bandgap reference voltage to cause a second resistor to conduct a reference current; and
mirroring the reference current through a current mirror to form the first current conducted through the first resistor.

20. The method of claim 19, further comprising:
adjusting a magnitude of the first current and a resistance of the first resistor to adjust the bias voltage.
